(19) United States
(12) Patent Application Publication
(10) Pub. No.: US 2013/0037946 A1
(43) Pub. Date: Feb. 14, 2013

(54) SEMICONDUCTOR CHIP INCLUDING BUMP HAVING BARRIER LAYER, AND MANUFACTURING METHOD THEREOF

(71) Applicants: Sung-Dong Kim, Seoul (KR); Hoo-Jeong Lee, Gyeonggi-do (KR); Eun-Kyung Kim, Seoul (KR); Young-Chang Joo, Seoul (KR); Gu-Sung Kim, Gyeonggi-do (KR)

(72) Inventors: Sung-Dong Kim, Seoul (KR); Hoo-Jeong Lee, Gyeonggi-do (KR); Eun-Kyung Kim, Seoul (KR); Young-Chang Joo, Seoul (KR); Gu-Sung Kim, Gyeonggi-do (KR)

(73) Assignee: FOUNDATION SEOUL TECHNOPARK, Seoul (KR)

(21) Appl. No.: 13/642,713

(22) PCT Filed: Apr. 21, 2011
(86) PCT No.: PCT/KR11/02898

§ 371 Date: Oct. 22, 2012

(30) Foreign Application Priority Data
Apr. 22, 2010 (KR) 10-2010-0037329

(51) Int. Cl. H01L 23/498; H01L 21/768

(52) U.S. Cl. 257/737; 438/613; 257/751; 257/E23.069; 257/E21.584

(57) ABSTRACT

A semiconductor chip includes a first substrate including a first surface and a second surface, a through-via plug passing through the first substrate, and a first conduction layer connected to an end of the through-via plug on the first surface, and a first bump including a first barrier layer on the first conduction layer, and a first solder layer for connecting the first substrate and a second substrate on the first barrier layer, and the first barrier layer includes a barrier material for preventing diffusion of a conductive material of the first conduction layer into the first solder layer.

### TECHNICAL FIELD

The present invention relates to a semiconductor chip, and in particular, to a semiconductor chip for use in a semiconductor package including a bump, a stack-type semiconductor package using the semiconductor chip and a method of fabricating the semiconductor chip.

### BACKGROUND ART

The capacity of semiconductor packages may be increased by using system-on-chip (SoC) and/or system-in-package (SiP) technologies. When these technologies are used, performance, power, costs, and size of semiconductor packages can be continuously improved at a system level.

SiP can be classified into a horizontal placement, a stacked structure, and an embedded structure, according to a physical architecture. From among these structures, a stacked structure may include a wire bonding structure, a combination of wire bonding and flip chip, a package-on-package (PoP) structure, or a terminal through-via structure. Layers of a stack-type semiconductor package having a stacked structure may each have a conductive connection terminal for an electrical connection with other layers, and a conductive connection terminal of a layer may be electrically connected to a conductive connection terminal of another layer.

A conductive connection terminal may be formed in a bump shape on an active surface or inactive surface of a layer. In this regard, conductive connection terminals may be arranged in such a way that when a layer of a stacked semiconductor package is stacked on another layer thereof, a conductive connection terminal of the layer contacts a conductive connection terminal of the another layer. Following the stacking a layer of a stacked semiconductor package on another layer thereof, heat and pressure are applied to the result structure to electrically and physically connect conductive connection terminals that contact each other. In this regard, according to a material for a conductive connection terminal, a specific resistance of the conductive connection terminal may increase and thus, signal power transmitted the respective layers may decrease.

### DETAILED DESCRIPTION OF THE INVENTION

### Technical Problem

As described above, due to the increase in specific resistances of conductive connection terminals that connect layers of a stack-type semiconductor package, loss of interlayer transmission signal may occur.

In response, to address the problem described above, the present invention provides a semiconductor chip having a conductive connection terminal structure for preventing an increase in specific resistance of a conductive connection terminal and a method of fabricating the same. These purposes are just examples, and the present invention is not limited thereto.

### Technical Solution

According to an aspect of the present invention, provided is a semiconductor chip. The semiconductor chip includes: a first substrate including a first surface and a second surface; a through-via plug passing through the first substrate; and a first bump including a first conduction layer connected to an end of the through-via plug on the first surface side, a first barrier layer on the first conduction layer, and a first solder layer for connecting the first substrate to a second substrate on the first barrier layer, wherein the first barrier layer includes a barrier material that prevents diffusion of a conductive material of the first conduction layer into the first solder layer.

In this regard, the semiconductor chip may further include a second bump including a second conduction layer connected to an end of the through-via plug on the second surface, a second barrier layer on the second conduction layer, and a second solder layer connecting the first substrate and a third substrate on the second barrier layer, wherein the second barrier layer includes a barrier material that prevents diffusion of a conductive material of the second conduction layer into the second solder layer.

In this regard, a first under bump layer may be further formed between the through-via plug and the first bump, and a second under bump layer is further formed between the through-via plug and the second bump.

The first conduction layer and the second conduction layer may each include Cu, the first solder layer and the second solder layer may each include Sn, and the first barrier layer and the second barrier layer may each include one or more selected from Ni, Ta, TaN, CuNi, TiCuNi, TiCu, NiV, Ti, TiW, and Cr—Cu.

In this regard, a redistribution layer may be further formed between the through-via plug and the first conduction layer, and the through-via plug and the first conduction layer are connected via the redistribution layer. In this regard, a first under bump layer may be further formed between the redistribution layer and the first bump.

In this regard, the end of the through-via plug on the first surface side may protrude from the first surface, and extends to cover a portion of the first surface.

In this regard, a horizontal cross-section size of the end of the through-via plug on the first surface side may be identical to a horizontal cross-section size of the first bump.

In this regard, the first substrate may be a silicon substrate, and a thickness of the first substrate may be in a range of 60 um to 500 um.

According to another aspect of the present invention, provided is an interposer for a semiconductor package. The interposer includes: a dummy substrate that includes a first surface and a second surface and does not include a circuit device therein; a through-via plug passing through the dummy substrate; and a first bump including a first conduction layer connected to an end of the through-via plug on the first surface side, a first barrier layer on the first conduction layer, and a first solder layer for connecting the dummy substrate to a second substrate on the first barrier layer, and wherein the first barrier layer includes a barrier material that prevents diffusion of a conductive material of the first conduction layer into the first solder layer.

In this regard, the interposer may further include a solder bump connected to an end of the through-via plug on the second surface.

In this regard, a first under bump layer may be further formed between the through-via plug and the first bump, and a second under bump layer may be further formed between the through-via plug and the solder bump.

According to another aspect of the present invention, provided is a method of fabricating a semiconductor chip. The method includes: providing a first substrate including a first surface, a second surface, and a through-via plug, wherein the through-via plug passes through the first substrate; forming a first conductive bump on an end of the through-via plug on the first surface; and forming a second conductive bump on an end of the through-via plug on the second surface, wherein the forming of the first conductive bump includes forming a first conduction layer connected to the end of the through-via plug on the first surface side, forming a first barrier layer on the first conduction layer, and forming a first solder layer on the first barrier layer to connect the first substrate and a second substrate.

In this regard, the forming of the second conductive bump may include forming a second conduction layer connected to an end of the through-via plug on the second surface, forming a second barrier layer on the second conduction layer, and forming a second solder layer on the second barrier layer to connect the first substrate to a third substrate.

In this regard, the first barrier layer includes a barrier material that prevents diffusion of a conductive material of the first conduction layer into the first solder layer.

In this regard, the method may further include forming a first under bump connected to an end of the through-via plug on the first surface between the providing of the first substrate and the forming of the first conductive bump; and forming a second under bump layer connected to an end of the through-via plug on the second surface between the providing of the first substrate and the forming of the second conductive bump.

In this regard, the providing of the first substrate may include: forming a through via hole passing through the first substrate, and forming the through-via plug in the through via hole.

In this regard, the first substrate is a silicon substrate, and the first substrate is subjected to grinding to make a thickness thereof to be in a range of 60 um to 500 um.

According to another aspect of the present invention, provided is a method of fabricating an interposer. The method includes: providing a dummy substrate including a first surface, a second surface, and a through-via plug, wherein the through-via plug passes through the dummy substrate; forming a first conductive bump on an end of the through-via plug on the first surface; and forming a second conductive bump on an end of the through-via plug on the second surface, wherein the forming of the first conductive bump includes forming a first conduction layer connected to the end of the through-via plug on the first surface side, forming a first barrier layer on the first conduction layer, and forming a first solder layer on the first barrier layer to connect the dummy substrate and a second substrate.

### Advantageous Effects

Embodiments of the present invention provide a semiconductor chip and an interposer each having a structure for preventing an increase in specific resistance of conductive connection terminals that connect layers of a stack-type semiconductor package when the respective layers are stacked, and methods of fabricating the same. The described effect is an example only, and the scope of the present invention is not limited thereto.

### DESCRIPTION OF THE DRAWINGS

FIG. 1 is a cross-sectional view of a semiconductor chip according to an embodiment of the present invention.

FIG. 2 is a cross-sectional view of a semiconductor chip according to another embodiment of the present invention.

FIG. 3 is a cross-sectional view of a semiconductor chip according to another embodiment of the present invention.

FIG. 4 is a cross-sectional view of an interposer according to an embodiment of the present invention.

FIG. 5 is a cross-sectional view of an interposer according to another embodiment of the present invention.

FIG. 6 is a cross-sectional view of a stack-type semiconductor package according to an embodiment of the present invention.

FIG. 7 is a cross-sectional view of a stack-type semiconductor package according to another embodiment of the present invention.

FIG. 8 is a cross-sectional view of a semiconductor chip for use in an embodiment of the present invention.

FIG. 9 is a view of a conductive bump for use in embodiments of the present invention.

FIG. 10 are views for explaining a phenomenon occurring at a boundary of a conduction layer and a solder layer when heat and pressure are applied to a stacked structure including the conduction layer and the solder layer.

FIG. 11 is a cross-sectional view of a conductive bump connection structure according to an embodiment of the present invention.

FIGS. 12 to 25 are views illustrating a method of fabricating a semiconductor chip according to an embodiment of the present invention.

FIG. 26 illustrates profiles of a connection structure of a through-via plug and a conductive bump, for use in embodiments of the present invention.

FIG. 27 shows simulation results of stress of a stack-type semiconductor package according to a difference between a radius of a through-via plug and a radius of a conductive bump.

FIG. 28 illustrates graphs schematically showing a degree of warpage measured with respect to a thickness of a substrate of a semiconductor chip.

### BEST MODE

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, dimensions of structures illustrated therein may be enlarged or reduced to increase accuracy of the inventive concept.

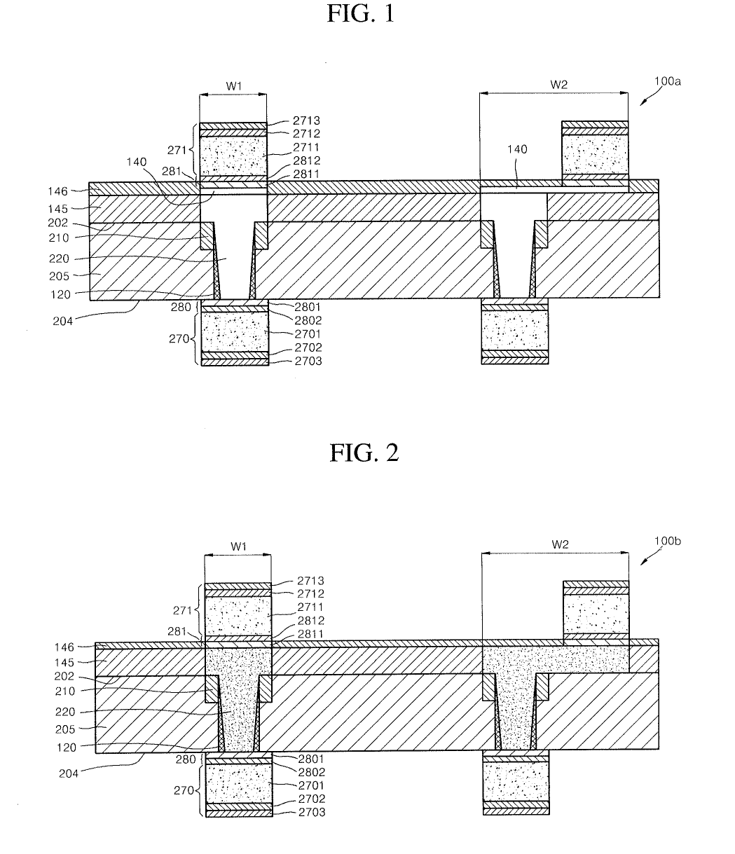

FIG. 1 is a cross-sectional view of a semiconductor chip 100a according to an embodiment of the present invention.

Referring to FIG. 1, provided is a substrate 205 including conductive pads 210 and a circuit device (not shown) connected to the conductive pads 210. A first surface 202 may be disposed opposite to a second surface 204, and for example, the first surface 202 and the second surface 204 may be respectively be a front surface and a rear surface of the substrate 205. The substrate 205 may include a circuit device that constitutes an active circuit, such as a memory device or a logic device.

The substrate 205 may be manufactured by using an apparatus and process for fabricating semiconductor chips. For example, the substrate 205 may include a Group IV semiconductor wafer or Groups III to V compound semiconductor wafer. Optionally, the substrate 205 may be provided by polishing a bottom surface of a semiconductor wafer to remove a predetermined thickness thereof.

Through-via plugs 220 may be provided extending through the substrate 205. For example, the through-via plugs 220 may extend from the first surface 202 to the second surface 204 through the substrate 205. For example, the through-via plugs 220 may be perpendicular to the first surface 202 and/or the second surface 204. According to a modified example of the present embodiment, the through-via plugs 220 may extend at a predetermined angle from the first surface 202 to the second surface 204 through the substrate 205. Optionally, the through-via plugs 220 may further extend protruding from the first surface 202 and/or the second surface 204 of the substrate 205.

The through-via plugs 220 may be electrically connected to conductive pads 210.

The number of through-via plugs 220 may be appropriately selected according to a semiconductor chip structure connected to the semiconductor chip 100a, and accordingly, the number of through-via plugs 220 is not limited to the present embodiment. For example, one through-via plug 220 may be provided in the substrate 205 or a plurality of through-via plugs 220 may be provided in the substrate 205. In the latter case, the through-via plugs 220 may be spaced apart from each other.

The through-via plugs 220 may be formed of a conductive material. For example, the through-via plugs 220 may have a stacked structure of barrier metal/barrier material and distribution metal. For example, the barrier metal/barrier material may include a stacked structure of one or more selected from titanium (Ti), cobalt (Co), tantalum (Ta), nickel (Ni), TiN, TaN, TaN, CuNi, TiCuNi, TiCu, NiV, TiW, and Cr—Cu. The distribution metal may include aluminum (Al) or copper (Cu). Such materials that constitute the through-via plugs 220 are examples only, and the present embodiment is not limited thereto.

An isolation insulation layer 120 may be provided between the through-via plugs 220 and the substrate 205. The isolation insulation layer 120 may prevent a direct contact between the through-via plugs 220 and the substrate 205. In FIG. 1, a thickness of the isolation insulation layer 120 increases in a direction from the first surface 202 to the second surface 204. However, the present embodiment is not limited to such a shape.

A redistribution layer 140 may be provided to be connected to at least a portion of through-via plugs 220 on the first surface 202 of the substrate 205. For example, the redistribution layers 140 may extend in a predetermined direction from top surfaces of the through-via plugs 220. The redistribution layers 140 may redistribute a distribution from the through-via plugs 220. The redistribution layers 140 may include an appropriate conductive material, for example, Al or Cu. The redistribution layers 140 and the through-via plugs 220 may be formed of a same material or different materials.

The redistribution layers 140 may be connected to a portion or all of the through-via plugs 220 that require redistribution. Accordingly, with respect to a portion of the through-via plugs 220 that does not require redistribution, the redistribution layers 140 may not be connected, or redistribution layers 140 may be disposed on only a portion thereof. Accordingly, the number of redistribution layers 140 may be 1, or 2 or more, and the present embodiment is not limited thereto.

First under bump layers 281 may be provided on the redistribution layers 140 disposed on the first surface 202. The first under bump layers 281 may enhance an adhesive force between the redistribution layers 140 and a first conductive bump 271 when the redistribution layers 140 and the first conductive bump 271 are connected to each other and/or may provide a barrier layer. According to a modified example of the present embodiment, a portion of the first under bump layers 281 may be directly connected to the through-via plugs 220 without the redistribution layers 140. The number of first under bump layers 281 may be 1 or 2 or more, and the present embodiment is not limited thereto.

The first under bump layers 281 may include, as illustrated in FIG. 1, two or more layers 2811 and 2812 including a barrier layer. However, according to another embodiment of the present invention, the first under bump layers 281 may include only one layer. Accordingly, the scope of the present invention is not limited to the structure of FIG. 1. According to an embodiment of the present invention, one of typical under bump metallurgy (UBM) structures may be optionally used as the first under bump layers 281.

The first under bump layers 281 may have a stacked structure of one or more materials selected from appropriate conductive materials, for example, titanium (Ti), cobalt (Co), tantalum (Ta), nickel (Ni), Cu, Al, TiN, TaN, CuNi, TiCuNi, TiCu, NiV, TiW, and Cr—Cu. For example, when the through-via electrodes 220 and the redistribution layers 140 include Cu, the first under bump layers 281 may have a stacked structure of Ti and Ni, for example, a stacked structure of Ti/Cu/Ni.

The first passivation layer 145 may be provided on the first surface 202 of the substrate 205 to expose at least a portion of top surfaces of the through-via plugs 220.

A second passivation layer 146 may be provided on the first passivation layer 145 and the redistribution layer 140 to expose at least a portion of the redistribution layer 140. The first passivation layer 145 and the second passivation layer 146 may each have a stacked structure of one or two or more selected from appropriate insulating materials, for example, an oxide, a nitride, and an oxynitride.

In FIG. 1, top surfaces of the first under bump layers 281 protrude from a top surface of the second passivation layer 146. However, according to embodiments of the present invention, top surfaces of the first under bump layers 281 may be disposed at the same level as or a lower level than the top surface of the second passivation layer 146.

According to embodiments of the present invention, the first surface 202 may be an active surface on which active devices are formed and the second surface 204 may be an inactive surface on which active devices are not formed. In this regard, the first passivation layer 145 and the second passivation layer 146 may be formed on only the active surface and may not be formed on the inactive surface.

Second under bump layers 280 may be provided on the second surface 204 of the substrate 205 to be connected to the through-via plugs 220. For example, the second under bump layer 280 may be disposed on bottom surfaces of the through-via plug 220. The structure of the second under bump layers 280 may be understood by referring to the description presented with respect to the first under bump layers 281, and the first under bump layers 281 and the second under bump layers 280 may be formed of a same material or different materials. The number of second under bump layers 280 may be 1 or 2 or more, and the present embodiment is not limited thereto.

The first conductive bumps 271 on the first surface 202 may be provided on the first under bump layers 281. The first under bump layers 281 may be disposed between the through-via plugs 220 and the first conductive bumps 271 to increase an adhesive force therebetween. Second conductive bumps 270 on the second surface 204 may be provided on the second under bump layers 280. The second under bump layers 280 are interposed between the through-via plugs 220 and the second conductive bumps 270 to increase an adhesive force therebetween. The first conductive bumps 271 and the second conductive bumps 270 may each include a solder layer, a barrier layer, and a conduction layer, and may be referred to as ‘a pillar bump.’

According to the semiconductor chip 100a described above, an adhesive force between the through-via plugs 220 and the second conductive bumps 270 may be enhanced by using the second under bump layers 280.

Furthermore, the second conductive bumps 270 on the second surface 204 may be electrically connected to the first under bump layers 281 on the first surface 202. That is, the semiconductor chip 100a may provide a vertical connection structure.

According to embodiments of the present invention, the semiconductor chip 100a of FIG. 1 may not include the second under bump layers 280 and the second conductive bumps 270.

According to a modified example of the present embodiment, constituents disposed above the first passivation layer 145 of the semiconductor chip 100a of FIG. 1 may not be formed. That is, the first under bump layers 281, the first conductive bumps 271, the second passivation layer 146, and the redistribution layers 140 may not be formed.

According to a modified example of the present embodiment, the second passivation layer 146 may not be formed.

FIG. 2 is a cross-sectional view of a semiconductor chip 100b according to another embodiment of the present invention.

The semiconductor chip 100b of FIG. 2 is modified from the semiconductor chip 100a of FIG. 1, and the difference therebetween is described below.

In FIG. 1, a width of the top surface of the through-via plug 220 is substantially fixed to, for example, ‘w1’. However, when the location of the through-via plug 220 is different from the location of the first conductive bump 271 connected thereto, for example, the redistribution layer 140 having a length of ‘w2’ is further stacked to electrically connect the through-via plug 220 to the first conductive bump 271.

Unlike the semiconductor chip 100a of FIG. 1, in the semiconductor chip 100b of FIG. 2, the width of the top surface of the through-via plug 220 is not fixed to only a single value, and may vary according to purpose, and for example, may be ‘w1’ or ‘w2’. In this regard, the redistribution layer 140, which is described with reference to FIG. 1, may not be used. In this regard, the second passivation layer 146 may be formed on at least a portion of the first passivation layer 145 and the through-via plug 220 to expose only a space for the first under bump layers 281. Alternatively, according to a modified example of the present embodiment, the second passivation layer 145 may not be formed.

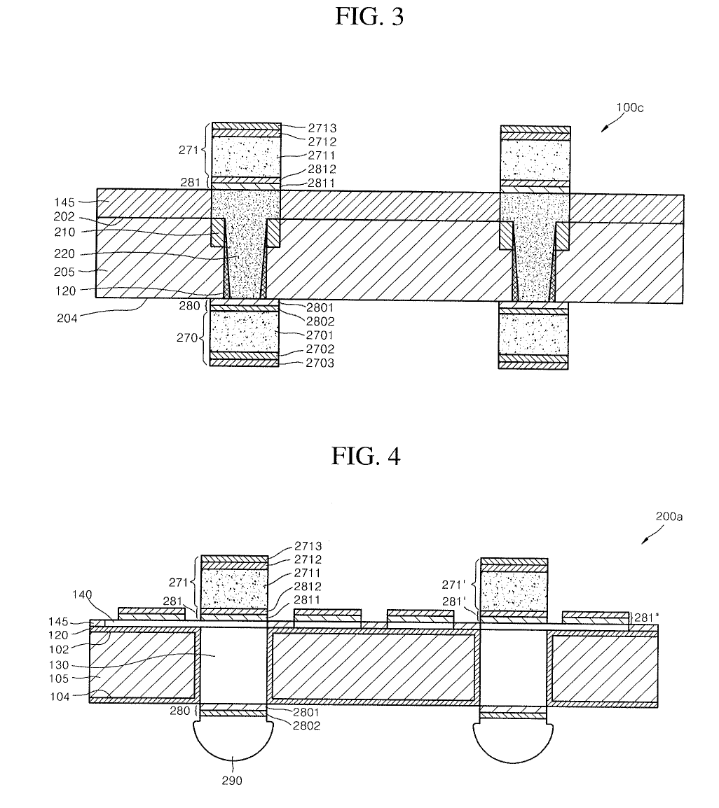

FIG. 3 is a cross-sectional view of a semiconductor chip 200a according to another embodiment of the present invention.

The semiconductor chip 100c of FIG. 3 is modified from the semiconductor chip 100a of FIG. 1, and the difference therebetween is described below.

In the semiconductor chip 100c of FIG. 3, locations of the through-via plugs 220 are the same as locations of the first conductive bumps 271 connected thereto. Accordingly, the redistribution layer 140 illustrated in FIG. 1 is not required. Accordingly, the second passivation layer 146 may not be further formed. The first under bump layer 281 may be formed on the exposed top surface of the through-via plug 220.

The semiconductor chips of FIGS. 1 to 3 have a conductive bump on both sides of a substrate. However, according to an embodiment of the present invention, a conductive bump may be formed on only one surface of the substrate.

FIG. 4 is a cross-sectional view of an interposer 200a according to an embodiment of the present invention.

Referring to FIG. 4, a dummy substrate 105 including a first surface 102 and a second surface 104 may be provided. The first surface 102 and the second surface 104 may be disposed opposite to each other, and may be, for example, a front surface and a rear surface of the dummy substrate 105, respectively. The dummy substrate 105 may not include a circuit device that constitutes an active circuit, such as a memory device or a logic device. Accordingly, the interposer 200a is distinguished from a semiconductor chip including a circuit device.

The dummy substrate 105 may be formed of various materials, and may be, for example, an insulating substrate, a semiconductor substrate, or a flexible substrate. For example, the dummy substrate 105 may be formed as a semiconductor wafer which is also used as a semiconductor chip. In this regard, the dummy substrate 105 may be manufactured by using an apparatus and process for manufacturing semiconductor chips, leading to a decrease in manufacturing costs of the dummy substrate 105. For example, the dummy substrate 105 may include a Group IV semiconductor wafer or Groups III to V compound semiconductor wafer. Optionally, the dummy substrate 105 may be provided by polishing a bottom surface of a semiconductor wafer to remove a predetermined thickness thereof.

Through-via plugs 130 may be provided passing through the dummy substrate 105. For example, the through-via plugs 130 may extend from the first surface 102 to the second surface 104 through the dummy substrate 105. For example, the through-via plugs 130 may be perpendicular to the first surface 102 and/or the second surface 104. According to a modified example of the present embodiment, the through-via plugs 130 may extend at a predetermined angle from the first surface 102 to the second surface 104 through the substrate 205. Optionally, the through-via plugs 130 may further extend protruding from the first surface 102 and/or the second surface 104 of the dummy substrate 105.

In the present specification, if a substrate includes silicon, ‘through via’ may also be referred to as ‘through silicon via (TSV.)’

The number of through-via plugs 130 may be appropriately selected according to structures of other semiconductor chips or interposers that are connected to the interposer 200b, and accordingly, the present embodiment is not limited thereto. For example, one through-via plug 130 may be provided in the dummy substrate 105 or a plurality of through-via plugs 130 may be provided in the dummy substrate 105. In the latter case, the through-via plugs 130 are spaced apart from each other.

The through-via plugs 130 may be formed of a conductive material. For example, the through-via plugs 130 may have a stacked structure of barrier metal/barrier material and distribution metal. For example, the barrier metal/barrier material may include a stacked structure of one or more selected from Ti, Co, Ta, Ni, TiN, TaN, CuNi, TiCuNi, TiCu, NiV, TiW, and Cr—Cu. The distribution metal may include Al or Cu. Such materials that constitute the through-via plugs 130 are examples only, and the present embodiment is not limited thereto.

An isolation insulation layer 120 may be provided between the through-via plugs 130 and the dummy substrate 105. The isolation insulation layer 120 may prevent a direct contact between the through-via plugs 130 and the dummy substrate 105. The isolation insulation layer 120 may further extend on the first surface 102 and the second surface 104 of the dummy substrate 105.

A redistribution layer 140 may be provided to be connected to at least a portion of through-via plugs 130 on the first surface 102 of the dummy substrate 105. For example, the redistribution layers 140 may extend in a predetermined direction from top or bottom surfaces of through-via plugs 130. The redistribution layers 140 may redistribute a distribution from the through-via plugs 130. For example, although FIG. 4 illustrates a first conductive bump 271′ formed on a first under bump layer 281′, even when the first conductive bump 271′ is formed on a first under bump layer 281″, the first conductive bump 271′ may be electrically connected to the through-via plug 130 by the redistribution layer 140. The redistribution layers 140 may include an appropriate conductive material, for example, Al or Cu.

The redistribution layers 140 may be connected to a portion or all of the through-via plugs 130 that require redistribution. Accordingly, with respect to a portion of the through-via plugs 130 that does not require redistribution, the redistribution layers 140 may not be connected, or redistribution layers 140 may be disposed on only a portion thereof. Accordingly, the number of first under bump layers 140 may be 1 or 2 or more, and the present embodiment is not limited thereto.

The redistribution layers 140 may be formed to be connected to at least a portion of the through-via plugs 130 by using a separate process after the through-via plugs 130 are formed.

Alternatively, the redistribution layers 140 may be integrally formed with the through-via plugs 130 when the through-via plugs 130 are formed. In this regard, a boundary between the redistribution layers 140 and the through-via plugs 130 may not exist.

A connection structure of the through-via plug 130 and the redistribution layer 140 may also be referred to as a ‘through via electrode.’ In addition, according to a modified example of the present embodiment, the interposer 200a may not include the redistribution layers 140, and in this regard, the through-via plug 130 may be referred to as a ‘through via electrode.’

First under bump layers 281 may have the same structure as the first under bump layers 281 described with reference to FIG. 1. In addition, first conductive bumps 271 may have the same structure as the first conductive bumps 271 described with reference to FIG. 1. In addition, second under bump layers 280 may have the same structure as the second under bump layers 280 described with reference to FIG. 1. In addition, second conductive bumps 270 may have the same structure as the first conductive bumps 270 described with reference to FIG. 2.

The passivation layer 145 may be provided on the first surface 102 of the dummy substrate 105 to expose at least a portion of the redistribution layer 140. The first passivation layer 145 may have a stacked structure of one or two or more selected from appropriate insulating materials, for example, an oxide, a nitride, and an oxynitride. Optionally, the passivation layer 145 may cover the redistribution layer 140 and may expose a top surface of the first under bump layer 281.

According to embodiments of the present invention, the first surface 102 may be an active surface on which active devices are formed and the second surface 104 may be an inactive surface on which active devices are not formed. In this regard, the passivation layer 145 may be formed only on the active surface and may not be formed on the inactive surface.

The second under bump layers 280 may be provided on the second surface 104 of the dummy substrate 105 to be connected to the through-via plugs 130. For example, the second under bump layer 280 may be disposed on a bottom surface of the through-via plug 130. The second under bump layer 280 may be understood by referring to the description presented with reference to the first under bump layer 281, and the second under bump layer 280 and the first under bump layer 281 may be formed of a same material or different materials. The number of second under bump layers 280 may be 1 or 2 or more, and the present embodiment is not limited thereto. According to an embodiment of the present invention, the second under bump layers 280 may have the same structure as the first under bump layers 281.

The first conductive bumps 271 on the first surface 102 may be provided on the first under bump layers 281. The first under bump layers 281 may be disposed between the ‘through-via electrode’ and the first conductive bumps 271 to increase an adhesive force therebetween. Second conductive bumps 290 on the second surface 104 may be provided on the second under bump layers 280. The second under bump layers 280 may be disposed between the ‘through-via electrodes’ and the second conductive bumps 290 to increase an adhesive force therebetween. The ‘through via electrode,’ as described above, may refer to a connection structure of the through-via plug 130 and the redistribution layer 140. If the interposer 200a does not include the redistribution layer 140, the ‘through via electrode’ may refer to the through-via plug 130.

The first conductive bumps 271 may each include a first solder layer 2713, a first conduction layer 2711, and a first barrier layer 2712, and a bump having such a structure may be referred to as a pillar bump. The first barrier layer 2712 may prevent diffusion of a conductive material included in the first conduction layer 2711 into the first solder layer 2713. The conductive material included in the first conduction layer 2711 may be Cu or Al. A cross-section of the pillar bump may be circular, tetragonal, or hexagonal.

The second conductive bumps 290 may include a solder layer, and may be referred to as a solder bump or a solder ball.

Due to the structure of the interposer 200a, the first conductive bumps 271 on the first surface 102 may be electrically connected to the second conductive bumps 290 on the second surface 104. That is, the interposer 200a may provide a vertical connection structure.

When the dummy substrate 105 consists of silicon, a through via plug 130 and/or the ‘through via electrode’ may be referred to as a through silicon via (TSV).

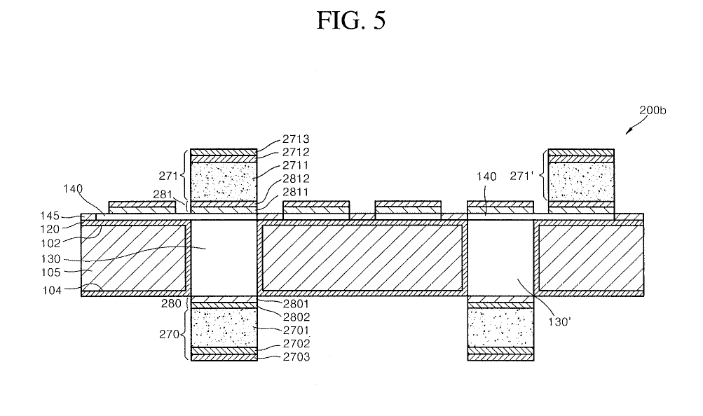

FIG. 5 is a cross-sectional view of an interposer 200b according to another embodiment of the present invention.

The interposer 200b of FIG. 5 is modified from the interposer 200a of FIG. 4. The location of a first conduction bump 271′ of the interposer 200b of FIG. 5 is different from the location of the through-via plug 130′ connected thereto. However, the first conduction bump 271′ is electrically connected to the through-via plug 130′ via the redistribution layer 140. Although FIG. 4 does not illustrate this structure, when the interposer 200a is described with reference to FIG. 4, such a structure is already described.

The interposer 200b of FIG. 5 may be different from the interposer 200a of FIG. 4 in the following point.

The interposer 200b of FIG. 5 may include second conduction bumps 270 (pillar bumps) on the second under bump layers 280. The second conduction bumps 270 may each include a second solder layer 2703, a second conduction layer 2701, and a second barrier layer 2702, and the second conduction bumps 270 and the first conduction bumps 271 may have the same structure and performance.

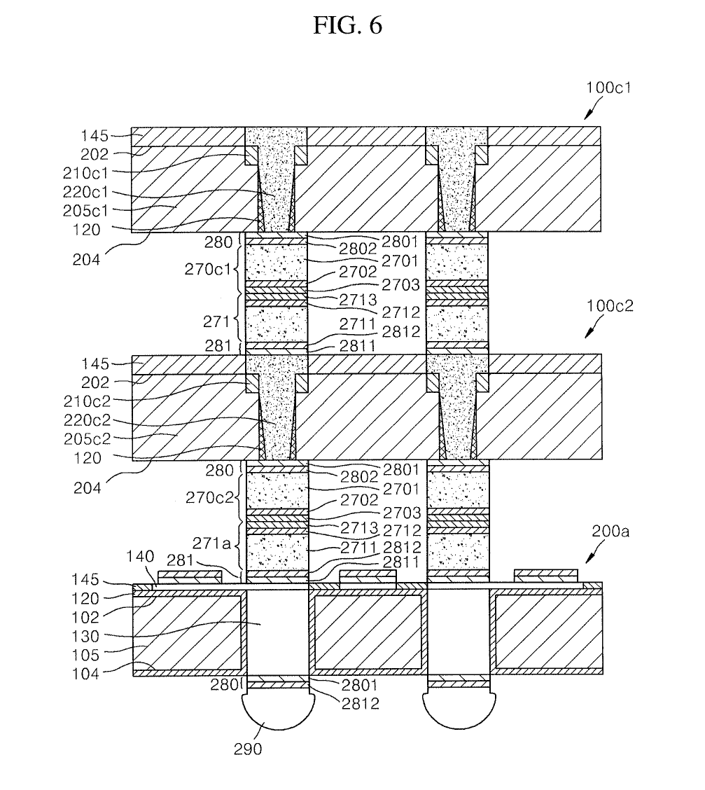

FIG. 6 is a cross-sectional view of a stack-type semiconductor package according to an embodiment of the present invention.

Referring to FIG. 6, the stack-type semiconductor package may have a stacked structure of an interposer 200a, a lower semiconductor chip 100c2 and an upper semiconductor chip 100c1. The lower semiconductor chip 100c2 may have the same structure of the semiconductor chip 100c of FIG. 5, and the upper semiconductor chip 100c1 corresponds to the semiconductor chip 100c of FIG. 5 from which constituents disposed above the passivation layer 145 are removed. The interposer 200a may have the same structure as the interposer 200a of FIG. 1.

The lower semiconductor chip 100c2 and the upper semiconductor chip 100c1 may be different products. For example, one of the lower semiconductor chip 100c2 and the upper semiconductor chip 100c1 may be a logic product and the other one may be a memory product. The stack-type semiconductor package may form a system-in-package (SIP) structure or a system-on-package (SOP) structure.

The lower semiconductor chip 100c2 may include lower through-via electrodes 220c2 passing through a semiconductor substrate 205c2. The lower through-via electrodes 220c2 may further pass by conductive pads 210c2 of the lower semiconductor chip 100c2, and furthermore, contact top surfaces of the conductive pads 210c2. The upper semiconductor chip 100c1 may include upper through-via electrodes 220c1 passing through a semiconductor substrate 205c1. The through-via electrodes 220c1 may further pass by conductive pads 210c1 of the upper semiconductor chip 100c1, and furthermore, may contact top surfaces of the conductive pads 210c1. When the semiconductor substrates 205c1 and 205c2 include silicon, the lower and upper through-via electrodes 220c1 and 220c2 may also be referred to as a through silicon via (TSV) electrode.

Second conductive bumps 270c2 of the lower semiconductor chip 100c2 may contact first conductive bumps 271a of the interposer 200a. Accordingly, the lower semiconductor chip 100c2 may be electrically connected to the interposer 200a. First conductive bumps 271c2 of the lower semiconductor chip 100c2 may contact second conductive bumps 270c1 of the upper semiconductor chip 100c1. Accordingly, the lower semiconductor chip 100c2 may be electrically connected to the upper semiconductor chip 100c1.

In the stack-type semiconductor package described above, one or more semiconductor chips (not shown) may be further provided on the upper semiconductor chip 100a. In addition, one or more interposers (not shown) may be further interposed between the semiconductor chips.

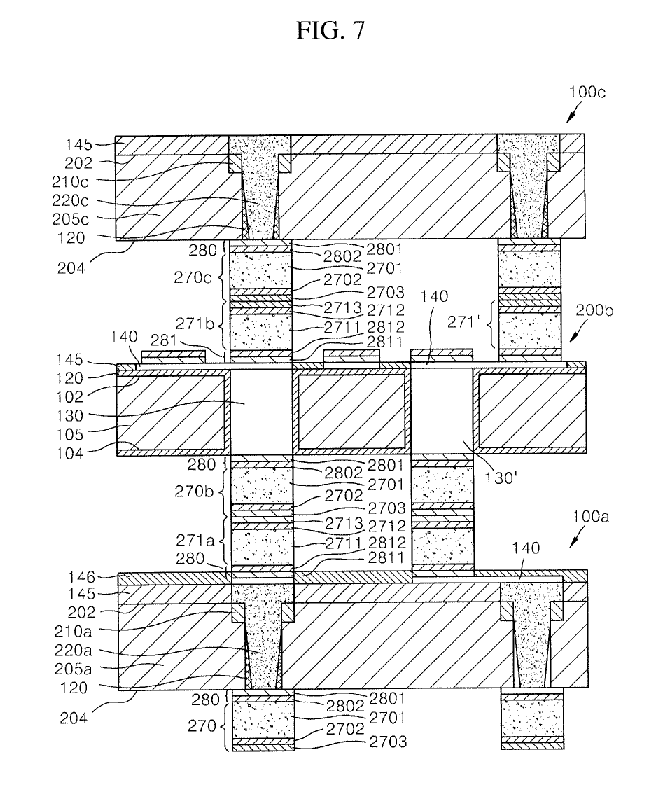

FIG. 7 is a cross-sectional view of a stack-type semiconductor package according to another embodiment of the present invention.

Referring to FIG. 7, the stack-type semiconductor package may have a stacked structure of an interposer 200b, a lower semiconductor chip 100a, and an upper semiconductor chip 100c. The lower semiconductor chip 100a may have the structure of the semiconductor chip 100a of FIG. 3, and the upper semiconductor chip 100c may have the structure of the semiconductor chip 100c of FIG. 5 from which constituents disposed above the passivation layer 145 are removed. The interposer 200b may have the structure of the interposer 200b of FIG. 2.

Like the description presented with reference to FIG. 6, the lower semiconductor chip 100a and the upper semiconductor chip 100c may be different products. The lower semiconductor chip 100a may include lower through-via electrodes 220a passing through a semiconductor substrate 205a. The lower through-via electrodes 220a further pass by conductive pads 210a of the lower semiconductor chip 100a and contact top surfaces of the conductive pads 210a. The upper semiconductor chip 100c may include upper through-via electrodes 220c passing through a semiconductor substrate 205c. The upper through-via electrodes 220c further pass by conductive pads 210c of the upper semiconductor chip 100 and contact top surfaces of the conductive pads 210c.

First conduction bumps 271a of the lower semiconductor chip 100a may contact second conduction bumps 270b of the interposer 200a. Accordingly, the lower semiconductor chip 100a may be electrically connected to the interposer 200a. Second conduction bumps 270c of the upper semiconductor chip 100c may contact the first conduction bumps 270b of the interposer 200b. Accordingly, the lower semiconductor chip 100a and the upper semiconductor chip 100c may be electrically connected to each other.

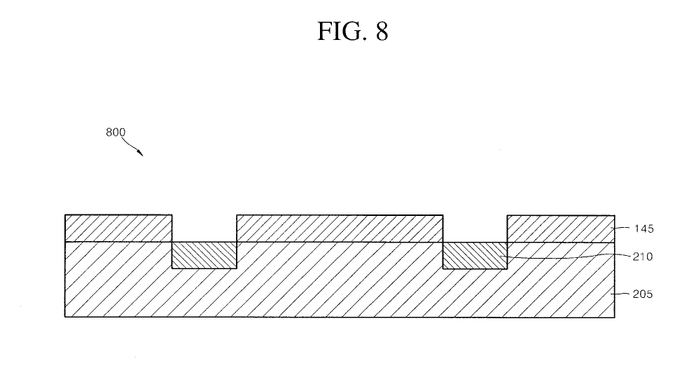

Other semiconductor chips or interposers may be further stacked under the lower semiconductor chip 100a. When other semiconductor chips or interposers are not stacked under the lower semiconductor chip 100a, the lower semiconductor chip 100a may not have the structure of FIG. 7. In this regard, for example, the lower semiconductor chip 100a may be replaced with the structure 800 of FIG. 8.

In the stack-type semiconductor package described above, one or more semiconductor chips (not shown) may be further provided on the upper semiconductor chip 100c. In addition, one or more interposers (not shown) may be further interposed between the semiconductor chips.

FIG. 8 is a cross-sectional view of a semiconductor chip 800 for use in an embodiment of the present invention.

Referring to FIG. 8, the semiconductor chip 800 may include a substrate 205, a conductive pad 210, and a passivation layer 145 exposing the conductive pads 210.

The semiconductor chips of FIGS. 3 to 5 may be fabricated from the semiconductor chip 800 of FIG. 8.

When other semiconductor chips or interposers are not further stacked under the lower semiconductor chip 100a, the semiconductor chip 800 of FIG. 8 can be replace with the lower semiconductor chip 100a of FIG. 7 when a solder layer is coated on conductive pads of the semiconductor chip 800 of FIG. 8.

Examples of combination of interposer and/or semiconductor chips of FIGS. 1 to 5 according to an embodiment of the present invention have been described with reference to FIGS. 6 to 8 and related explanation. In addition, other combinations are also obvious.

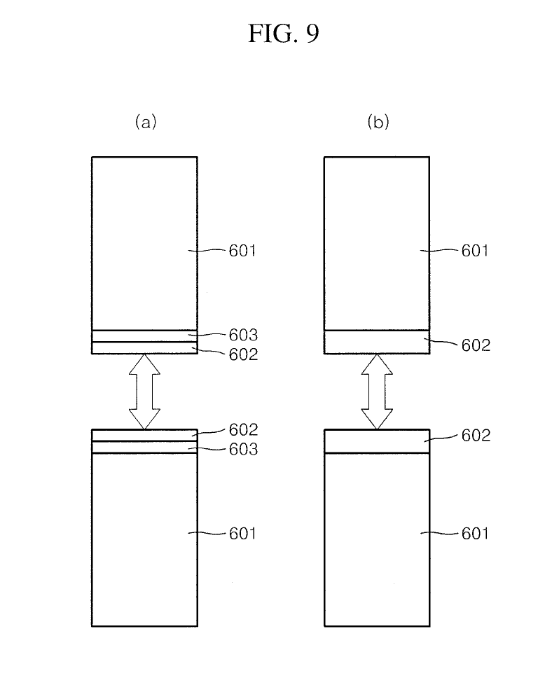

FIG. 9 is a view of a conductive bump for use in embodiments of the present invention.

The interposers and semiconductor chips of FIGS. 1 to 7 include a conductive bump (pillar bump) having a structure corresponding to FIG. 9A. The conductive bumps may each include a conduction layer 601, a solder layer 602, and a barrier layer 603. As illustrated in FIG. 9A, two conductive bumps are disposed to face each other and then, the solder layers 602 are brought into contact and heat and pressure are applied thereto to combine the conductive bumps while the two solder layers 602 are molted. The conduction layer 601 may include Cu or Al, and the solder layer 602 may include Sn. The barrier layer 603 may have a stacked structure of one or more materials selected from Ti, Co, Ta, Ni, Cu, Al, TiN, TaN, CuNi, TiCuNi, TiCu, NiV, TiW, and Cr—Cu.

FIG. 9B is a view of a modified example of the conductive bumps of FIG. 9A. Unlike FIG. 9A, the conductive bumps of FIG. 9B each do not include the barrier layer 603 between the conduction layer 601 and the solder layer 602.

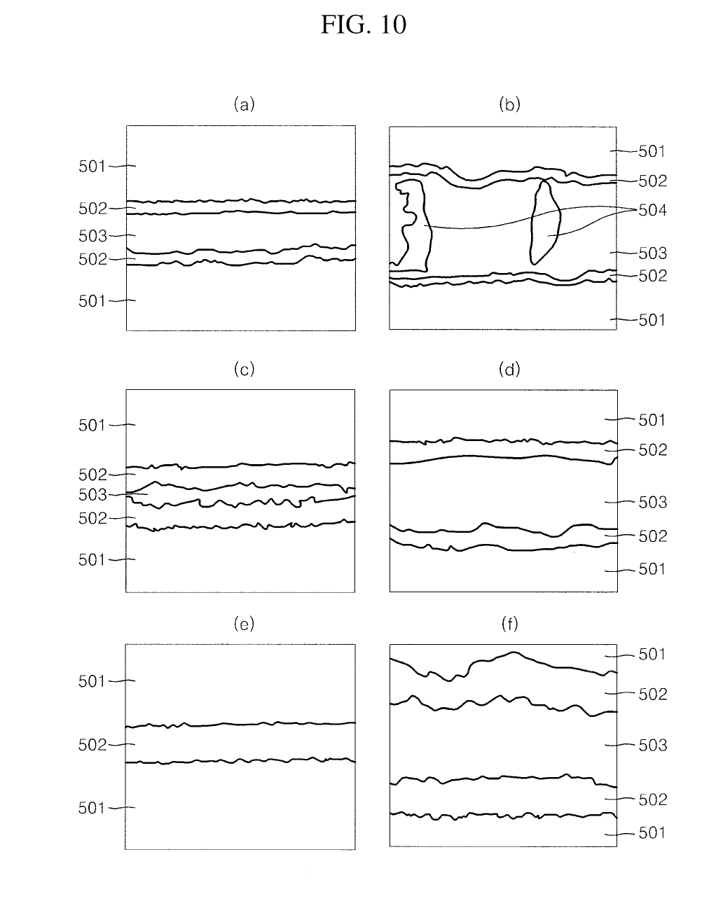

As illustrated in FIG. 9B, two conductive bumps are disposed to face each other and then, the solder layers 602 are brought into contact and heat and pressure are applied thereto to combine the conductive bumps while the two solder layers 602 are molted. In this regard, metal included in the conduction layer 601 may diffuse into the solder layer 602 to combine with metal included in the solder layer 602. Due to the combination, a material having high specific resistance value may be generated, and thus, a resistance of the conductive bumps may increase. FIG. 10 shows this phenomenon.

FIG. 10 are views for explaining a phenomenon occurring at a boundary of a conduction layer and a solder layer when heat and pressure are applied to a stacked structure including the conduction layer and the solder layer.

FIG. 10 illustrates a cross-sectional view of a contact portion formed according to a contact condition, when the solder layers 602 of two conductive bumps are brought into contact as illustrated in FIG. 9B and then heat and pressure are applied thereto. When heat and pressure are applied, copper of the conduction layer 601 may diffuse into the solder layer 602, so that the copper is combined with tin of the solder layer 602 to form an intermetallic compound. The combination may vary according to a combination temperature and a combination pressure.

FIGS. 10A, 10C, and 10E are cross-sectional views of a contact portion when a higher combination pressure is applied than FIGS. 10B, 10D, and 10F.

FIGS. 10A and 10B illustrate cross-sectional views of a contact portion when the combination temperature is 250 degrees Celsius, FIGS. 10C and 10D illustrate cross-sectional views of a contact portion when the combination temperature is 300 degrees Celsius, and FIGS. 10E and 10F illustrate cross-sectional views of a contact portion when the combination temperature is 350 degrees Celsius.

In FIG. 10, reference numerals 501, 502, 503, and 504 respectively denote a Cu layer, a Cu₃Sn layer, a Cu₆Sn₅ layer, and a Sn layer. Specific resistances according to a material that constitute a layer are shown in Table 1.

TABLE 1

| Materials | Specific resistance (μ\acute{ }Ω-cm) |
|---|---|
| Cu | 1.7 |
| Cu₃Sn | 8.93 |
| Cu₆Sn₅ | 17.5 |
| Sn | 11.5 |

As shown in Table 1, since a specific resistance of a Cu₆Sn₅ layer is 17.5 μΩ-cm, that is, the specific resistance of the Cu₆Sn₅ layer is very higher than specific resistances of other layers, a thicker Cu₆Sn₅ layer may lead to a higher resistance of the contact portion of a conductive bump. Accordingly, since the Cu₆Sn₅ layer is formed by diffusion of Cu into a Sn layer, if the diffusion of Cu into the Sn layer is prevented, generation of the Cu₆Sn₅ layer may be suppressed.

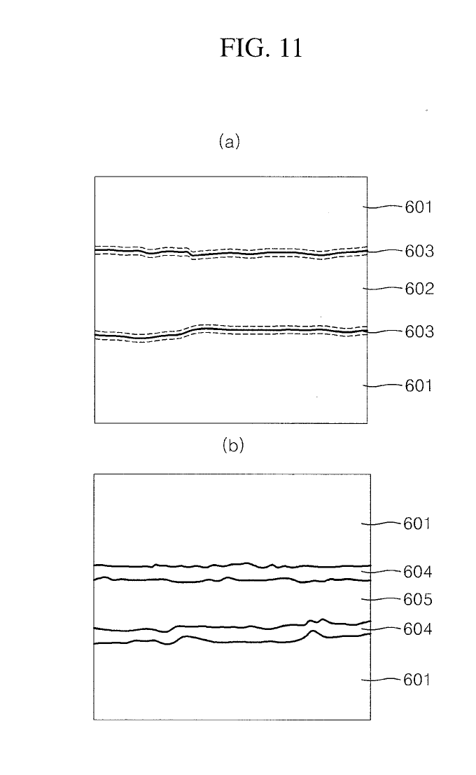

FIG. 11 is a cross-sectional view of a conductive bump connection structure according to an embodiment of the present invention.

FIGS. 11A and 11B illustrate, like FIGS. 9A and 9B, cross-sectional views of contact portions formed according to a contact condition, when the solder layers 602 of two conductive bumps are brought into contact and then heat and pressure are applied thereto. Herein, the conduction layer 601, the solder layer 602, and the barrier layer 603 may respectively include Cu, Sn, and Ni.

As described with FIG. 9A, when the barrier layer 603 exists, the barrier layer 603 may prevent diffusion of a material that constitutes the conduction layer 601 into the solder layer 602. Accordingly, it was confirmed that the formation of the Cu6Sn5 layer, which leads to an increase in a resistance of a contact portion of the conductive bump, is prevented (see FIG. 11A.)

However, as illustrated in FIG. 9B, when the barrier layer does not exist, a material that constitutes the conduction layer 601 diffuses into the solder layer 602. Accordingly, a Cu₆Sn₅ layer 605, which increases a resistance of a contact portion of the conductive bump, is formed together with a Cu₃Sn layer 604 (FIG. 11B).

Accordingly, when conductive bumps according to an embodiment of the present invention illustrated in FIGS. 1 to 7 are used, a decrease in interlayer signal power of a semiconductor package having a stacked structure may be reduced.

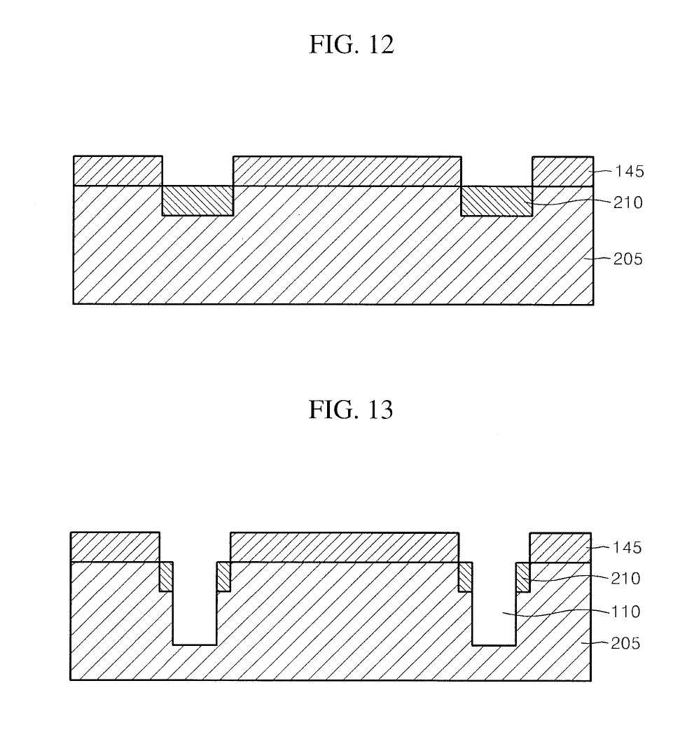

FIGS. 12 to 25 are views illustrating a method of fabricating a semiconductor chip according to an embodiment of the present invention. In particular, a method of fabricating the semiconductor chip 100c of FIG. 5 is described in detail.

Referring to FIG. 12, a semiconductor chip including the substrate 205, the conductive pad 210, and the passivation layer 145 is provided.

Referring to FIG. 13, a through-via hole 110 passing through the substrate 205 may be formed. The through-via hole 110 may not pass through the substrate 205. The through-via hole 110 may be formed by laser drilling, dry etching, or wet etching.

Since in the case of the laser drilling, a focus is adjustable, the laser drilling may enable formation of the through-via hole 110 without photolithography. On the other hand, when dry etching or wet etching are used, the through-via hole 110 may be optionally formed by using etch mask (not shown) formed by photolithography.

The through-via hole 110 may have a varying shape according to an etching method. For example, the through-via hole 110 may be formed to have a predetermined diameter vertically. According to another embodiment of the present invention, the through-via hole 110 may have a tapered shape that has a varying diameter according to height.

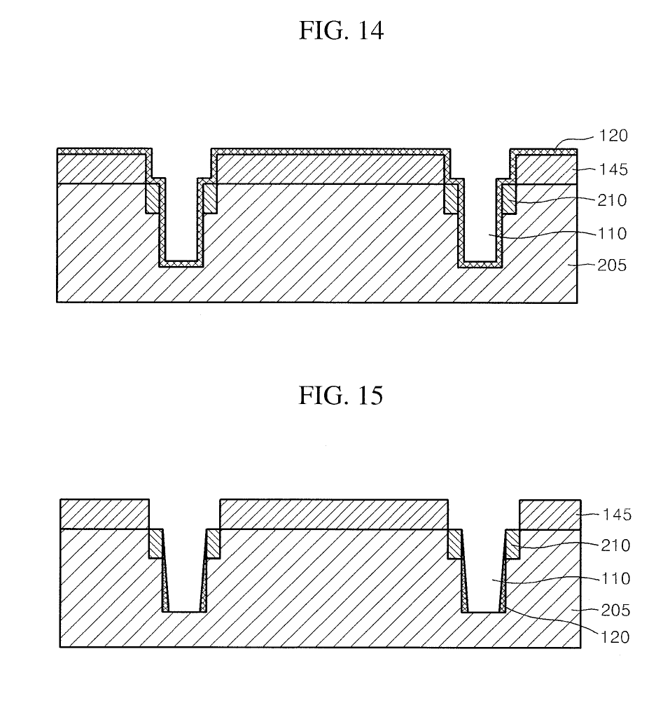

Referring to FIG. 14, the isolation insulation layer 120 may be formed on a surface of the substrate 205 exposed by the through-via hole 110. The isolation insulation layer 120 may be controllable to have such a thickness that the isolation insulation layer 120 does not fill the through-via hole 110. The isolation insulation layer 120 may extend on the passivation layer 145.

For example, the isolation insulation layer 120 may be formed by optionally heat-oxidizing the surface of the substrate 205 exposed by the through-via hole 110. According to another embodiment of the present invention, the isolation insulation layer 120 may be formed by chemical vapor deposition (CVD). The isolation insulation layer 120 may include an oxide layer, a nitride layer, or a stacked structure thereof.

Referring to FIG. 15, a portion of the isolation insulation layer 120 other than the portion thereof on the exposed portion of the through-via hole 110 in the substrate 205 may be entirely removed. To do this, spacer etching may be used.

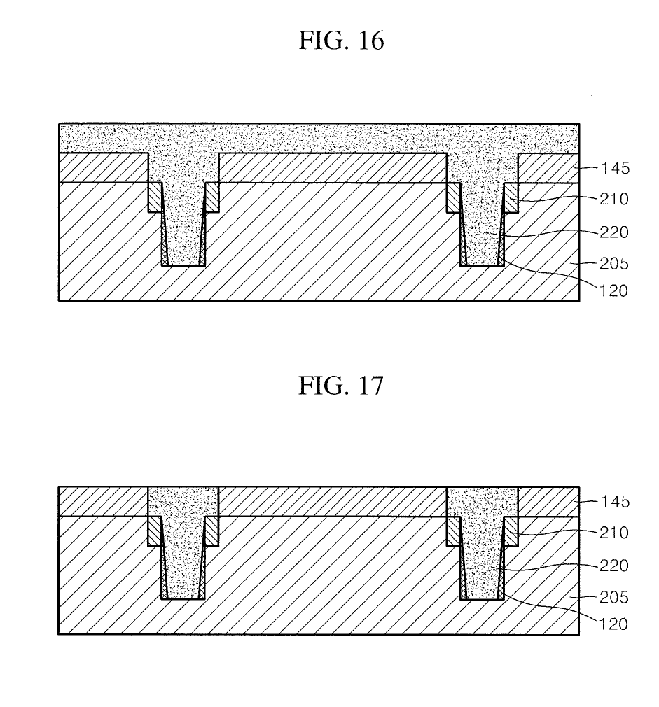

Referring to FIG. 16, the through-via plug 220 may be formed filing the through-via hole 110. In this regard, the through-via plug 220 may extend protruding from the passivation layer 145. For example, the through-via plug 220 may be formed by filling the through-via hole 110 with an appropriate conductive material, and then, a planarization process is formed thereon. For example, the through-via plug 220 may include a barrier metal/barrier material and a distribution metal. The filling with a conductive material may be performed by plating. In this regard, when a through-via plug is formed by plating, plating conditions may be adjusted to suppress the formation of voids in the through-via plug 220. For example, during electroplating, when a current value is about 0.2 μm/minute, the through-via plug 220 may be filled without the formation of voids.

A barrier layer may be formed by sputtering or CVD. A metal distribution may be formed by sputtering and/or plating. For example, a metal distribution including copper may be typically formed by plating.

Referring to FIG. 17, an upper portion of metal that is stacked to form the through-via plug 220 illustrated in FIG. 16 is planarized by, for example, CMP to expose the passivation layer 145.

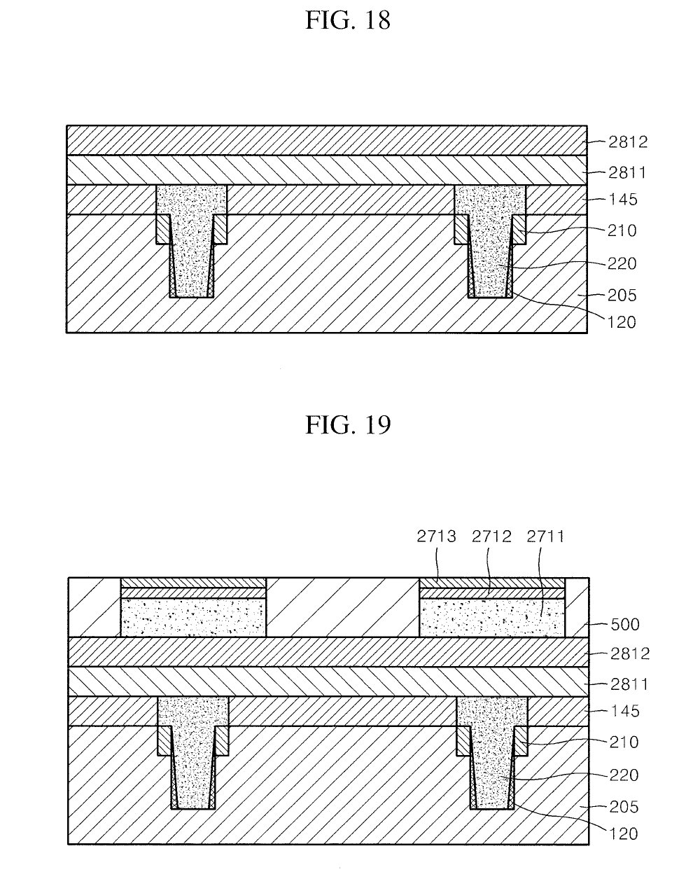

Referring to FIG. 18, a first under bump layer may be stacked on the through-via plug 220 exposed by the passivation layer 145. The first under bump layer may consist of two or more layers 2811 and 2812. This may be formed by, for example, sputtering and/or lift-off. As described above, when the through-via plugs 220 includes copper, the first under bump layers 2811 and 2812 may include a stacked structure of Ti and Ni, for example, a stacked structure of Ti/Cu/Ni.

Referring to FIG. 19, a photoresist 500 is coated on the first under bump layers 2811 and 2812, and then, patterned by using a mask to form a pattern of the photoresist 500 exposing a portion of the first under bump layers 2811 and 2812 corresponding to the through-via plug 220. The conduction layer 2711, the barrier layer 2712, and the solder layer 2713 may be sequentially stacked in this stated order on the exposed first under bump layers 2811 and 2812. The first under bump layers 2811 and 2812 may include, for example, Cu, and may be formed by electroplating. The barrier layer 2712 may include, for example, Ni, and may be formed by electroless plating.

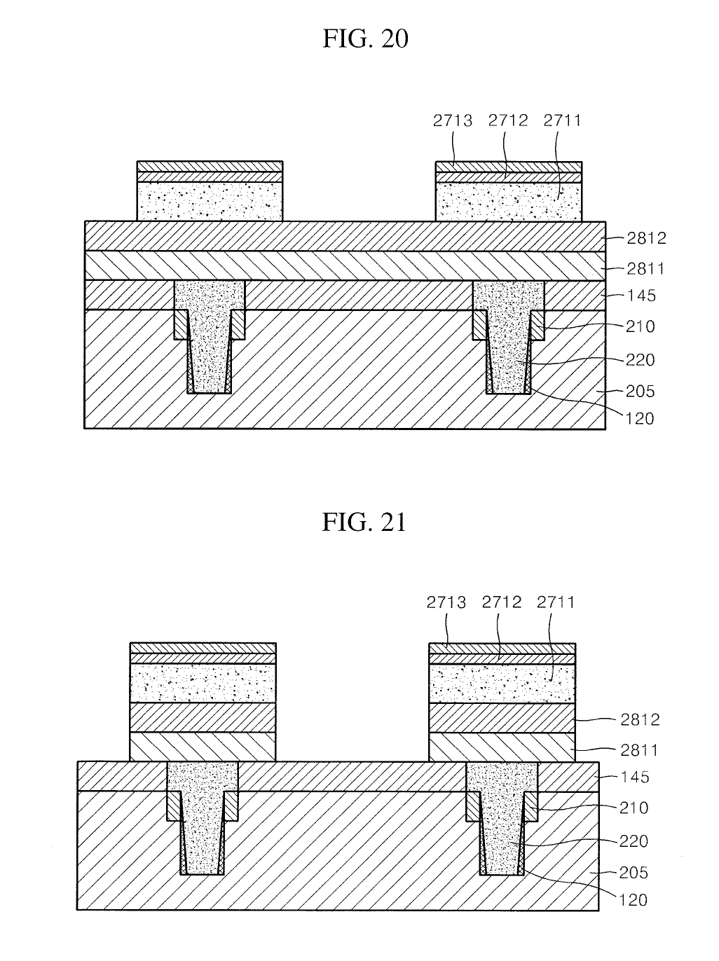

Referring to FIG. 20, the photoresist 500 may be removed by using a photoresist stripper.

Referring to FIG. 21, a portion of the first under bump layers 2811 and 2812 other than a portion of the first under bump layers 2811 and 2812 immediately contacting the first conduction layer 2711 disposed under the first under bump layers 2811 and 2812 may be removed.

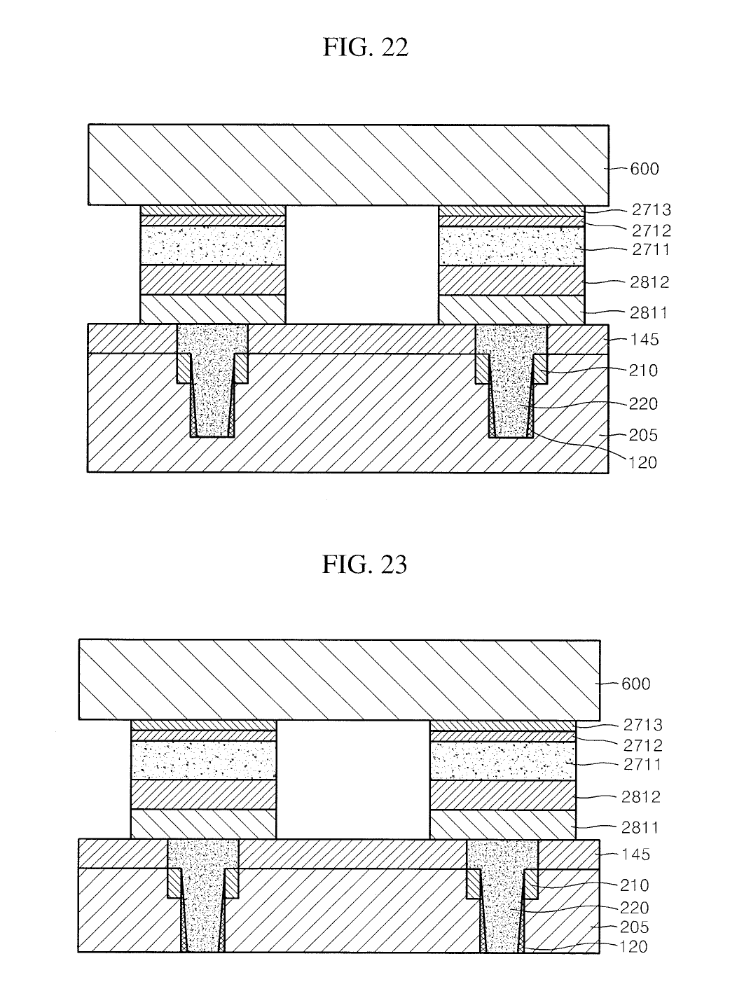

Referring to FIG. 22, a sacrificial protecting layer 600 may be formed on the first solder layer 2713 with an adhesive layer (not shown) therebetween. For example, the sacrificial protecting layer 600 may be attached to the first solder layer 2713 through the adhesive layer (not shown). The sacrificial protecting layer 600 may include an appropriate insulating material, for example, glass. The sacrificial protecting layer 600 may, in a subsequent process, protect a structure disposed above the passivation layer 145 of the substrate 205.

Referring to FIG. 23, a surface of the substrate 205 opposite to the surface thereof on which the passivation layer 145 is formed, is planarized by, for example, CMP, thereby exposing the through-via plug 220 toward the opposite side. When in FIG. 13, the through-via hole 110 passes through the substrate 205 and the substrate 205 is sufficiently thin, the CMP planarization may not be performed.

According to an embodiment of the present invention, the substrate 205 of the semiconductor chip may have a thickness of 60 um to 500 um.

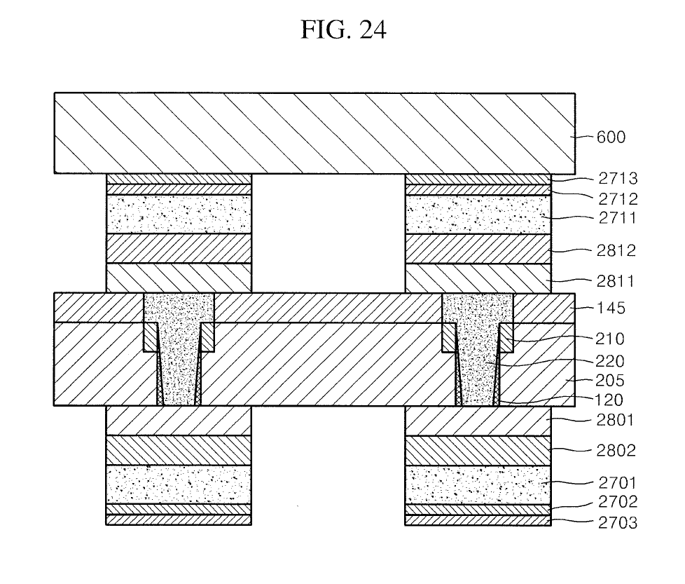

Referring to FIG. 24, the processes corresponding to FIGS. 18 to 21 are performed on the opposite surface of the substrate 205 away from the passivation layer 145 to form the second under bump layers 2801 and 2802, the second conduction layer 2701, the second barrier layer 2702, and the second solder layer 2703 on the opposite surface.

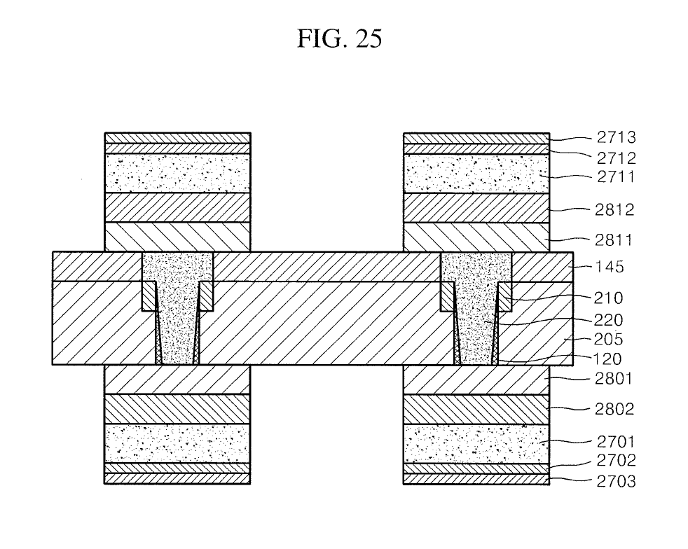

Referring to FIG. 25, the adhesive layer (not shown) and the sacrificial protecting layer 600 are removed.

Hereinbefore, an example of a method of fabricating a semiconductor chip of FIG. 5 has been described. However, it is obvious to one of ordinary skill in the art that the semiconductor chips of FIGS. 3 and 4 can be fabricated by using the methods described above.

The description with respect to embodiments of the present invention is provided for the purpose of exemplary illustration and explanation. Accordingly, the present invention is not limited to the embodiments, and within the scope of the present invention, the embodiments may be corrected and modified by, for example, combination thereof by one of ordinary skill in the art.

According to an embodiment of the present invention, a horizontal cross-sectional size of an end of a through-via plug may be identical to a horizontal cross-sectional size of a conductive bump that contacts the end. In this regard, the horizontal cross-section of the end of the through-via plug may be circular, tetragonal, or hexagonal, and a horizontal cross-sectional shape of the conductive bump that contacts the end may correspond to a horizontal cross-sectional shape of the end of the through-via plug.

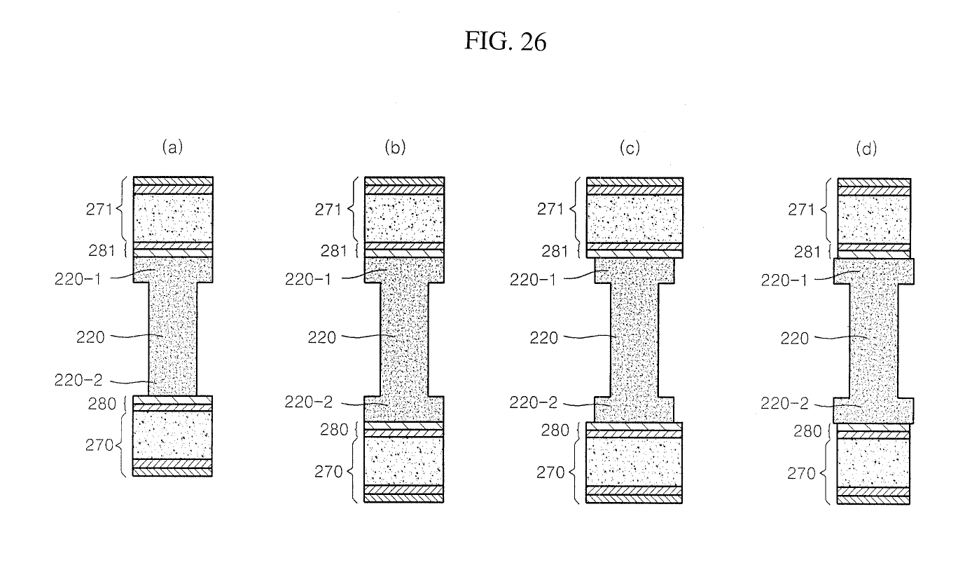

For example, a horizontal cross-section of the end of the through-via plug and a horizontal cross-section of the conductive bump may be circular. In this regard, when the sizes of the horizontal cross-sections are the same, a stack-type semiconductor package fabricated by stacking the semiconductor chips described above may have a minimized structural defect. This is described with reference to FIGS. 26 to 28.

FIG. 26 illustrates profiles of a connection structure of a through-via plug and a conductive bump, for use in embodiments of the present invention.

FIG. 26A illustrates the through-via plug 220 and the conductive bumps 270 and 271 illustrated in FIG. 3, and FIG. 26B illustrates a modified example of the structure of FIG. 26A. Referring to FIG. 26A, an end 220-1 of the through-via plug 220 has an area wider than that of the other end 220-2, and referring to FIG. 26B, the end 220-1 of the through-via plug 220 has the same area as the other end 220-2. Referring to FIG. 26B, a portion of the through-via plug 220 other than the end 220-1 and the other end 220-2 is formed in the substrate 205, and the end 220-1 protrudes upward from the first surface 202 and the other end 220-2 protrudes downward from the second surface 204. The other end 220-2 illustrated in FIG. 26B may be formed by adding a typical plating process between the process of FIG. 23 and the process of FIG. 24. Accordingly, it is obvious that the structure of FIG. 26B is used instead of the stacked structure of the second conductive bump, the second under bump layer, the through-via plug, the redistribution layer, the first under bump layer, and the second conductive bump of FIGS. 1 to 25.

Referring to FIG. 26B, a diameter of the through-via plug 220 is the same as diameters of the conductive bumps 270 and 271, referring to FIG. 26C, the diameter of the through-via plug 220 is smaller than the diameters of the conductive bumps 270 and 271, and referring to FIG. 26D, the diameter of the through-via plug 220 is greater than the diameters of the conductive bumps 270 and 271. In this regard, sizes of bump lower layers 280 and 281 may be identical to diameters of the through-via plug 220 or the conductive bumps 270 and 271.

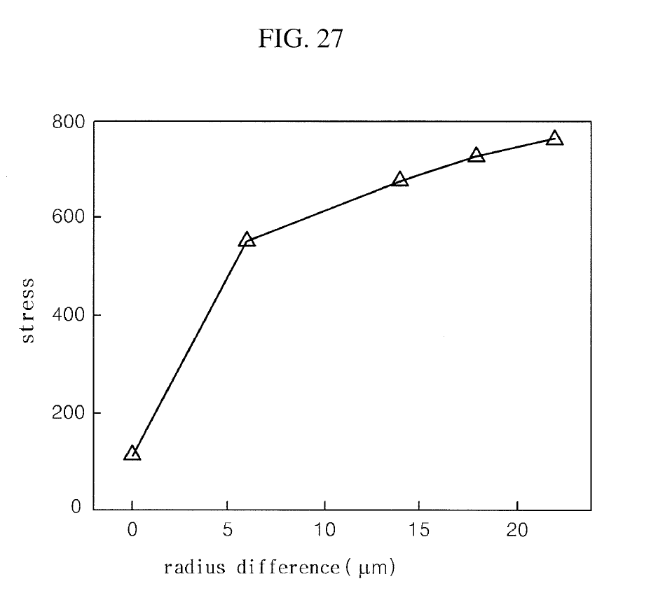

FIG. 27 shows simulation results of stress applied to a stack-type semiconductor package according to a difference between a radius of a through-via plug and a radius of a conductive bump.

Referring to FIG. 27, when a difference between a radius of a through-via plug and a radius of a conductive bump is 0, stress applied to a stack-type semiconductor package is minimized. Accordingly, a radius of a horizontal cross-section of a through-via plug of semiconductor chip may be identical to a radius of a horizontal cross section of a conductive bump. This is also applied when the horizontal cross-sections are not circular. That is, the shape and size of the through-via plug may be identical to the shape and size of the conductive bump.

When different semiconductor chips or interposers are stacked on particular semiconductor chips of a stack-type semiconductor package, the structure of FIG. 26B may be included. However, when different semiconductor chips or interposers are stacked on either a top surface or a bottom surface of a particular semiconductor chip, the structure of FIG. 26A may be included.

Also, the first substrate may be a silicon substrate, and in this regard, a thickness of the first substrate may be in a range of 60 μm to 500 μm.

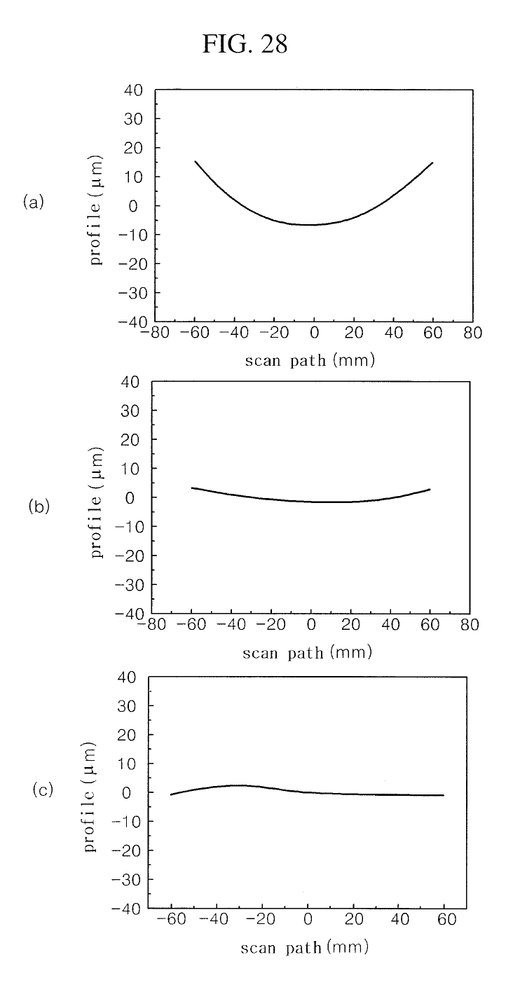

FIG. 28 illustrates graphs schematically showing a degree of warpage measured with respect to a thickness of a substrate of a semiconductor chip. FIG. 28A is a deformed profile of a substrate having a thickness of 39.3 μm, FIG. 28B is a deformed profile of a substrate having a thickness of 60 μm, and FIG. 28C is a deformed profile of a substrate having a thickness of 90 μm. Referring to FIG. 28, when a thickness of a substrate is small, the substrate is greatly deformed, and when a thickness of a substrate is 60 μm or more, a curvature radius thereof is 0.005 μm or lower, the deformation of the substrate was substantially reduced. Accordingly, by making a thickness of the substrate to be 60 μm or more, damage of a stack-type semiconductor package due to stress was substantially reduced. In addition, the thickness of the substrate may be 500 μm or lower. This is because when a through via hole is formed in a substrate having a thickness of greater than 500 μm by laser drilling, dry etching, or wet etching, an aspect ratio of a through via hole increases.

In the claims of the present invention, a ‘first substrate’ may be the substrate 205 of FIGS. 1 to 3, and a ‘dummy substrate’ may be a dummy substrate 105 of FIGS. 4 and 5. In addition, in the claims of the present invention, the ‘first surface’ may be the first surface 202 of FIGS. 1 to 3 and/or the first surface 102 of FIGS. 4 and 5. Alternatively, the ‘first surface’ may be the second surface 204 of FIGS. 1 to 3 and/or the second surface 104 of FIGS. 4 and 5. In addition, in the claims of the present invention, the ‘second surface’ may refer to an opposite surface of the ‘first surface’. In addition, in the claims of the present invention, the ‘through-via plug’ may be the through-via plug 220 of FIGS. 1 to 3 or the through-via plug 130 of FIGS. 4 and 5, and the ‘first conduction layer’, the ‘first barrier layer’, the ‘first solder layer,’ and the ‘first bump’ may respectively be the first conduction layer 2711, the first barrier layer 2712, the first solder layer 2713, and the first conductive bump 271 of FIGS. 1 to 5. In addition, in the claims of the present invention, the ‘first under bump layer’ and the ‘redistribution layer’ may respectively be the first under bump layer 281 and the redistribution layer 140 of FIGS. 1 to 5. In addition, in the claims of the present invention, the ‘through via hole’ may be the through-via hole 110 of FIGS. 13 to 15.

The description with respect to the particular embodiments of the present invention is provided for the purpose of exemplary illustration and explanation. Accordingly, the present invention is not limited to the embodiments, and within the scope of the present invention, the embodiments may be corrected and modified by, for example, combination thereof by one of ordinary skill in the art.

1. A semiconductor chip comprising:
a first substrate comprising a first surface and a second surface;
a through-via plug passing through the first substrate; and
a first bump comprising a first conduction layer connected to an end of the through-via plug on the first surface, a first barrier layer on the first conduction layer, and a first solder layer for connecting the first substrate to a second substrate on the first barrier layer,
wherein the first barrier layer comprises a barrier material that prevents diffusion of a conductive material of the first conduction layer into the first solder layer.

2. The semiconductor chip of claim 1, further comprising a second bump comprising a second conduction layer connected to an end of the through-via plug on the second surface, a second barrier layer on the second conduction layer, and a second solder layer connecting the first substrate and a third substrate on the second barrier layer, wherein the second barrier layer comprises a barrier material that prevents diffusion of a conductive material of the second conduction layer into the second solder layer.

3. The semiconductor chip of claim 2, wherein a first under bump layer is further formed between the through-via plug and the first bump, and a second under bump layer is further formed between the through-via plug and the second bump.

4. The semiconductor chip of claim 2, wherein the first conduction layer and the second conduction layer each comprise Cu, the first solder layer and the second solder layer each comprise Sn, and the first barrier layer and the second barrier layer each comprise one or more selected from Ni, Ta, TaN, CuNi, TiCuNi, TiCu, NiV, Ti, TiW, and Cr—Cu.

5. The semiconductor chip of claim 2, wherein a redistribution layer is further formed between the through-via plug and the first conduction layer, and the through-via plug and the first conduction layer are connected via the redistribution layer.

6. The semiconductor chip of claim 5, wherein a first under bump layer is further formed between the redistribution layer and the first bump.

7. The semiconductor chip of claim 2, wherein the end of the through-via plug on the first surface side protrudes from the first surface, and extends to cover a portion of the first surface.

8. An interposer for a semiconductor package, the interposer comprising:
a dummy substrate that comprises a first surface and a second surface and does not comprise a circuit device therein;
a through-via plug passing through the dummy substrate; and
a first bump comprising a first conduction layer connected to an end of the through-via plug on the first surface, a first barrier layer on the first conduction layer, and a first solder layer for connecting the dummy substrate to a second substrate on the first barrier layer, and
wherein the first barrier layer comprises a barrier material that prevents diffusion of a conductive material of the first conduction layer into the first solder layer.

9. The interposer of claim 8, further comprising a solder bump connected to an end of the through-via plug on the second surface.

10. The interposer chip of claim 9, wherein a first under bump layer is further formed between the through-via plug and the first bump, and a second under bump layer is further formed between the through-via plug and the solder bump.

11. A method of fabricating a semiconductor chip, the method comprising:
providing a first substrate comprising a first surface, a second surface, and a through-via plug, wherein the through-via plug passes through the first substrate;
forming a first conductive bump on an end of the through-via plug on the first surface; and
forming a second conductive bump on an end of the through-via plug on the second surface,
wherein the forming of the first conductive bump comprises forming a first conduction layer connected to the end of the through-via plug on the first surface, forming a first barrier layer on the first conduction layer, and forming a first solder layer on the first barrier layer to connect the first substrate and a second substrate.

12. The method of claim 11, wherein the forming of the second conductive bump comprises forming a second conduction layer connected to an end of the through-via plug on the second surface, forming a second barrier layer on the second conduction layer, and forming a second solder layer on the second barrier layer to connect the first substrate to a third substrate.

13. The method of claim 11, wherein the first barrier layer comprises a barrier material that prevents diffusion of a conductive material of the first conduction layer into the first solder layer.

14. The method of claim 11, further comprising
forming a first under bump connected to an end of the through-via plug on the first surface between the providing of the first substrate and the forming of the first conductive bump; and
forming a second under bump layer connected to an end of the through-via plug on the second surface between the providing of the first substrate and the forming of the second conductive bump.

15. The method of claim 11, wherein the providing of the first substrate comprises:
forming a through via hole passing through the first substrate, and
forming the through-via plug in the through via hole.

16. A method of fabricating an interposer, the method comprising:
providing a dummy substrate comprising a first surface, a second surface, and a through-via plug, wherein the through-via plug passes through the dummy substrate;
forming a first conductive bump on an end of the through-via plug on the first surface; and
forming a second conductive bump on an end of the through-via plug on the second surface,
wherein the forming of the first conductive bump comprises forming a first conduction layer connected to the end of the through-via plug on the first surface, forming a first barrier layer on the first conduction layer, and forming a first solder layer on the first barrier layer to connect the dummy substrate and a second substrate.
